(19) United States
(12) Patent Application Publication
(10) Pub. No.: US 2025/0081574 A1
(43) Pub. Date: Mar. 6, 2025

(54) METHOD FOR IMPROVING SHORT-CIRCUIT CAPABILITY OF ENHANCEMENT-MODE GaN HEMT AND ITS DEVICE STRUCTURE

(71) Applicant: Peking University, Beijing (CN)

(72) Inventors: Jin WEI, Beijing (CN); Jingjing YU, Beijing (CN)

(73) Assignee: Peking University, Beijing (CN)

(21) Appl. No.: 18/820,338

(22) Filed: Aug. 30, 2024

(30) Foreign Application Priority Data
Aug. 31, 2023 (CN) 202311109267.X

(51) Int. Cl. H01L 29/40; H01L 23/31; H01L 29/20; H01L 29/66; H01L 29/778

(52) U.S. Cl. CPC H10D 64/111; H01L 23/3171; H10D 30/015; H10D 30/475; H10D 62/8503

(57) ABSTRACT

Embodiments of the present application provides a method for improving the short-circuit capability of an enhancement-mode (E-mode) GaN HEMT and its device structure. This is achieved by depositing metal in the active region between the gate and the source, adjacent to the source region of a conventional E-mode GaN HEMT, the metal is directly connected with the source of the conventional E-mode GaN HEMT. The conventional E-mode GaN HEMT is combined with a gate-source-shorted depletion-mode (D-mode) GaN HEMT to form a complete E-mode GaN HEMT with improved short-circuit capability. By clamping the saturation current of the complete device through the D-mode GaN HEMT, the saturation current density of the E-mode GaN HEMT can be reduced, and the purpose of improving the short-circuit capability is finally realized.

### CROSS-REFERENCE TO RELATED APPLICATION

The present application claims priority to Chinese Patent Application No. 202311109267.X filed on Aug. 31, 2023, and titled “METHOD FOR IMPROVING SHORT-CIRCUIT CAPABILITY OF ENHANCEMENT-MODE GaN HEMT AND ITS DEVICE STRUCTURE”, which is incorporated herein by reference in its entirety.

### TECHNICAL FIELD

The present application relates to an enhancement-mode (E-mode) gallium nitride high electron mobility transistor (GaN HEMT), and more particularly to an E-mode GaN HEMT with improved short-circuit capability, belonging to the technical field of semiconductor devices.

### BACKGROUND

Gallium nitride high electron mobility transistors (GaN HEMTs) have excellent characteristics such as low conduction loss and high switching frequency. Power electronic circuits with higher efficiency and power density have been widely used. To improve the safety of power electronic circuits and simplify the design of power device gate driving circuits, in actual use, it is more desirable to use enhancement-mode (E-mode) GaN HEMTs. However, in actual power switching circuits, due to potential occurrences like load shorts, incorrect gate control signals, high-side and low-side power transistor punch-through, GaN HEMTs are prone to short-circuit phenomena when operating at high voltages. At this time, there are high drain voltage (V_{DS}) and high drain current (I_{D}) in GaN HEMTs simultaneously, resulting in high-density heat generation, which can cause GaN devices to fail or even be damaged. To solve this problem, researchers have proposed some methods to improve the short-circuit capability of GaN devices.

Ohio State University designed a short-circuit protection circuit and proposed a three-step short-circuit protection scheme [1]. It can quickly detect the short-circuit fault, reduce the gate voltage of GaN HEMT to enhance the short-circuit capability of the device, and turn off the GaN HEMT in case of determining a short-circuit event. The experimental results show that this scheme can shorten the short-circuit fault detection time of GaN HEMTs from 2 μs to tens of nanoseconds. However, the short-circuit protection circuit will make the design of the whole system more complicated.

North Carolina State University proposed a method for connecting a low-voltage Si depletion-mode (D-mode) MOSFET with gate-source shorted in series with the source of a GaN transistor to improve the short-circuit capability [2]. The Si D-mode MOSFET has a lower saturation current density, which can reduce the saturation current of the entire device. However, this dual-chip technology may introduce other parasitic problems.

Transphorm, Inc. has proposed a GaN device structure that can reduce the saturation current density. In the device width direction, the two-dimensional electron gas (2DEG) conducting channel under the gate is partially removed [3], which ultimately extends the short-circuit withstand time of the GaN HEMTs to 3 μs. However, the length, width and spacing of the removed 2DEG conducting channel under the gate need to be designed reasonably.

At present, there is still a need for a technical solution that can reduce the saturation current density of GaN HEMTs to enhance the short-circuit capability.

### REFERENCES

[1] X. Lyu et al., “A Reliable Ultrafast Short-Circuit Protection Method for E-Mode GaN HEMT,” in IEEE Transactions on Power Electronics, vol. 35, no. 9, pp. 8926-8933 September 2020, doi: 10.1109/TPEL.2020.2968865.
[2] A. Kanale and B. J. Baliga, “Achieving Short Circuit Capability for 600 V GaN FETs Using a Gate-Source-Shorted Si Depletion-Mode MOSFET in Series with the Source,” 2020 IEEE Workshop on Wide Bandgap Power Devices and Applications (WiPDA), Suita, Japan, September 2020, pp. 1-6, doi: 10.1109/WiPDAAsia49671.2020.9360275.
[3] D. Bisi, J. Gritters, T. Hosoda, M. Kamiyama, B. Cruse, Y. Huang, J. Mckay, G. Gupta, R. Lal, C. Neufeld, P. Zuk, Y. Wu, P. Parikh and U. Mishra, “Short-circuit capability demonstrated for GaN power switches,” APEC, Phoenix, AZ, USA, June 2021, pp. 370-375, doi: 10.1109/APEC42165.2021.9486987.

### SUMMARY

The purpose of the present application is to provide a method for improving the short-circuit capability of an enhancement-mode (E-mode) gallium nitride high electron mobility transistor (GaN HEMT) by reducing the saturation current density. This method aims to address the issue of GaN devices being susceptible to short-circuit occurrences in power electronic circuits.

The technical solution of the present application is as follows:

A method for improving the short-circuit capability of an E-mode GaN HEMT, comprising depositing metal in an active region between a gate and a source, adjacent to a source region of a conventional E-mode GaN HEMT, the metal being directly connected with the source of the conventional E-mode GaN HEMT to form a composite structure that combines a conventional E-mode GaN HEMT and a depletion-mode (D-mode) gate-source-shorted GaN HEMT, forming a complete E-mode GaN HEMT with improved short-circuit capability.

In the complete E-mode GaN HEMT of the present application, a conventional E-mode GaN HEMT shares the source with a D-mode GaN HEMT. After turning on the gate of the complete E-mode GaN HEMT, as the gate voltage (V_{GS}) and drain voltage (V_{DS}) increase, the gate-source-shorted D-mode GaN HEMT will be the first to enter the saturation region, where the drain current (I_{D}) of the entire device is the saturation current of the D-mode GaN HEMT. With further increases in V_{GS} and V_{DS}, the In of the complete E-mode GaN HEMT will not increase anymore, because the saturation current of the entire device is already limited by the gate-source-shorted D-mode GaN HEMT. Thus, by depositing metal in the active region near the source between the gate and the source of the conventional E-mode GaN HEMT, an E-mode GaN HEMT with reduced saturation current density can be fabricated, achieving the purpose of improving the short-circuit capability.

The E-mode GaN HEMT can be a p-GaN gate HEMT or a GaN HEMT with MIS gate structure, or a GaN HEMT with gate structure formed by fluorine ion implantation.

The application provides an E-mode GaN HEMT with improved short-circuit capability, consisting of a substrate, and a sequential stack of a buffer layer, a channel layer and a barrier layer on the substrate. The source and drain are located on two sides of the active region on the barrier layer. The gate structure is located between the source and the drain, and the gate is located on the gate structure. A passivation layer is formed between the source and the gate, as well as between the gate and the drain. Metal is deposited in the active region adjacent to the source between the gate and the source, directly connected with the source and separated from the gate by the passivation layer.

In the E-mode GaN HEMT with improved short-circuit capability above, the metal that is directly connected with the source and between the gate and source can located either on the barrier layer or on the passivation layer. When the metal is located on the barrier layer, a Schottky-gate D-mode GaN HEMT is formed. When a passivation layer of a certain thickness (such as 2 to 30 nm) is retained below the metal, a MIS-gate D-mode GaN HEMT is formed.

In the E-mode GaN HEMT with improved short-circuit capability above, the substrate can be a Si substrate, a SiC substrate, a sapphire substrate or a GaN substrate. The buffer layer can be made of at least one of GaN, AlN, InGaN, AlGaN, AlInGaN and similar materials, or combinations thereof. The channel layer can be made of GaN, InGaN, AlGaN, AlInGaN, or other materials. The barrier layer can be made of at least one of GaN, AlN, AlGaN, InGaN, AlInGaN, or combinations thereof.

In the E-mode GaN HEMT with improved short-circuit capability above, the gate structure can be one of a p-GaN gate structure (i.e., a p-type GaN cap layer), a MIS gate structure, or a gate structure formed through fluorine ion implantation.

The present application takes the p-GaN gate structure as an example and provides a method for preparing the above-mentioned E-mode GaN HEMT with improved short-circuit capability, comprising the following steps:
1) sequentially growing a buffer layer, a channel layer, a barrier layer, and a p-type GaN layer on a substrate;
2) etching the p-type GaN layer to form a gate p-type GaN cap layer;
3) depositing a passivation layer on the barrier layer and the gate p-type GaN cap layer structure;
4) etching the passivation layer on the barrier layer to form grooves at the source and drain regions, and then depositing electrode metal to form the source and drain while retaining grooves for subsequent metal deposition between the gate and the source adjacent to the source;
5) forming device isolation;

It is noted that, the following methods can be used to form device isolation: ion implantation in the passivation layer region around the p-GaN gate HEMT, using one or more combinations of F, N, B, Ar, Fe ions, etc. to make the passivation layer, the barrier layer and the electron-conducting channel layer beneath form a device isolation region; or, etching the passivation layer region in the periphery of the p-GaN gate HEMT, etching the barrier layer in this region and the electron-conducting channel layer underneath, so that the two-dimensional electron gas (2DEG) disappears.
6) etching the passivation layer on the gate p-type GaN cap layer structure to form grooves for depositing a gate metal, and then depositing the gate metal to form the gate;
7) depositing metal on the grooves between the gate and the source adjacent to the source, the metal being directly connected with the source, to form a D-mode GaN HEMT metal.

In the above step 4), the grooves retained between the gate and the source adjacent to the source can be located on the barrier layer, or located on the partially etched passivation layer.

In addition, modifications in the length, thickness, doping concentration and other parameters of each region in the E-mode GaN HEMT device fall within the purview of this application, contingent upon diverse design prerequisites and fabrication methods. It is worth noting that the focus of the present application is combining a conventional structure E-mode GaN HEMT with a D-mode GaN HEMT, which can clamp the saturation current of the entire device. It is understood that, within the scope of the present application, there may be instances of other structures and other variations. Furthermore, different instances, structures, and processes can be combined with each other to achieve the same purpose.

### Beneficial Effects of the Present Application

The present application provides an E-mode GaN HEMT with improved short-circuit capability and its manufacturing method. The design of the device structure can reduce the saturation current density of the E-mode GaN HEMT, and ultimately improve the short-circuit capability.

### BRIEF DESCRIPTION OF THE DRAWINGS

FIG. 1 is an effect diagram after completion of step 1) of Embodiment 1;

FIG. 2 is an effect diagram after completion of step 2) of Embodiment 1;

FIG. 3 is an effect diagram after completion of step 3) of Embodiment 1;

FIG. 4 is an effect diagram after completion of step 4) of Embodiment 1;

FIG. 5 is an effect diagram after completion of step 5) of Embodiment 1;

FIG. 6 is an effect diagram after completion of step 6) of Embodiment 1;

FIG. 7 is an effect diagram after completion of step 7) of Embodiment 1;

FIG. 8 is an effect diagram after completion of step 8) of Embodiment 1;

FIG. 9 is a cross-sectional view of an E-mode GaN HEMT with a p-GaN gate structure as depicted in Embodiment 1 of the present application;

FIG. 10 is a cross-sectional view of an E-mode GaN HEMT with a p-GaN gate structure as depicted in Embodiment 2 of the present application;

FIG. 11 is the output characteristic curves of the E-mode GaN HEMT with a p-GaN gate structure provided by Embodiment 1 (right) and a conventional E-mode GaN HEMT device (left).

### DETAILED DESCRIPTION

The present application will be further described in detail below in conjunction with the accompanying drawings and embodiments. It should be understood that the specific embodiments described herein are only used to explain the present application and not intended to limit the present application.

### Embodiment 1

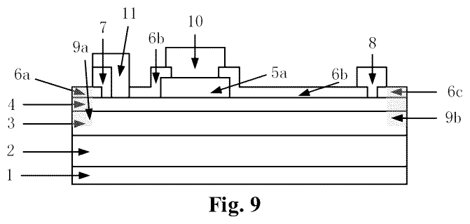

The embodiment provides an E-mode GaN HEMT device structure with a p-GaN gate structure and improved short-circuit capability, as shown in FIG. 9, comprising:
a substrate 1, which can be a Si substrate, a SiC substrate, a sapphire substrate or a GaN substrate;
a buffer layer 2, which can reduce the leakage current of the device and increase the breakdown voltage, and can be made of at least one of GaN, AlN, InGaN, AlGaN, AlInGaN, or a combination thereof;
a channel layer 3 for providing electronic-conducting channel, which can be made of GaN, InGaN, AlGaN, or AlInGaN;
a barrier layer 4 for generating two-dimensional electron gas (2DEG) by
polarization effect, which may be made of at least one of GaN, AlN, AlGaN, InGaN, AlInGaN, or a combination thereof;
a p-GaN gate structure depleting the 2DEG, a gate p-type GaN cap layer 5a;
passivation layers 6a, 6b and 6c used as the surface passivation layers of the p-GaN gate HEMT, which can be made of SiO₂ or Si₃N₄;
p-GaN-gate HEMT source 7;
p-GaN-gate HEMT drain 8;
fluorine-ion implanted device isolation areas 9a and 9b for isolation between different p-GaN-gate HEMT;
p-GaN-gate HEMT gate 10;
D-mode GaN HEMT metal 11.

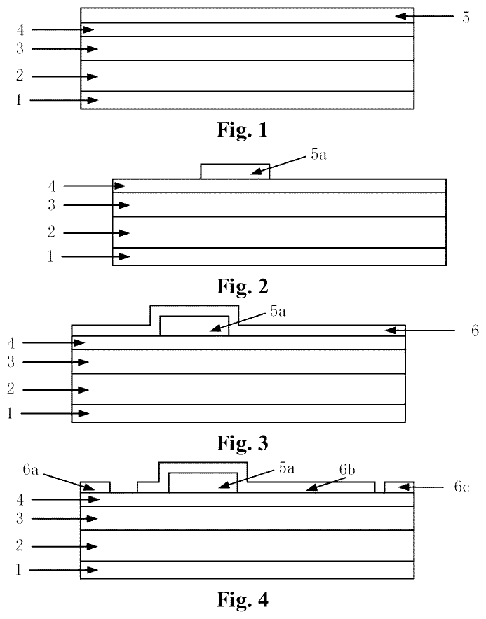

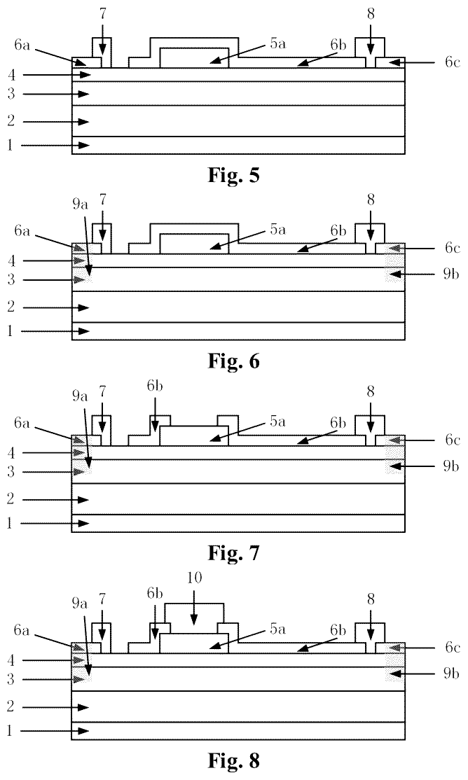

The preparation steps are as follows:
1) epitaxially growing the buffer layer 2, the channel layer 3, the barrier layer 4, and the p-type GaN layer 5 on the substrate 1 in sequence, as shown in FIG. 1;
2) etching the p-type GaN layer 5 to form the gate p-type GaN cap layer 5a, as shown in FIG. 2;
3) depositing the passivation layer 6 on the barrier layer 4 and the gate p-type GaN cap layer 5a, as shown in FIG. 3;
4) etching the passivation layer 6 to form separate passivation layers 6a, 6b and 6c, as shown in FIG. 4;
5) depositing electrode metal on the barrier layer 4 to form the source 7 and drain 8 of the p-GaN gate HEMT, and retaining grooves for depositing Schottky metal between the gate and the source, adjacent to the source 7, as shown in FIG. 5;
6) forming isolation regions 9a and 9b between different p-GaN gate HEMTs by fluorine ion implantation, as shown in FIG. 6;
7) etching the passivation layer 6b on the gate p-type GaN cap layer 5a to form grooves, as shown in FIG. 7;
8) depositing gate electrode metal on the gate p-type GaN cap layer 5a to form the gate 10, as shown in FIG. 8;
9) depositing metal in the grooves on the source electrode 7 on the barrier layer 4 and adjacent to the source electrode 7 to form a D-mode GaN HEMT metal 11, as shown in FIG. 9.

In order to intuitively illustrate the advantages of the proposed device mentioned above, a conventional p-GaN gate HEMT without Schottky metal was also fabricated on the same wafer. After testing, as shown in FIG. 11, the output characteristic curves of the two devices at V_{GS}=6 V show that the saturation current density of the conventional device has exceeded 400 mA/mm, whereas the saturation current density of the proposed device is only 100 mA/mm. The saturation current density of the proposed device is significantly reduced. At the same time, the on-resistance Ron of the proposed device is only slightly increased, showing that the inclusion of Schottky metal does not have a significant effect on the conduction loss of the device.

### Embodiment 2

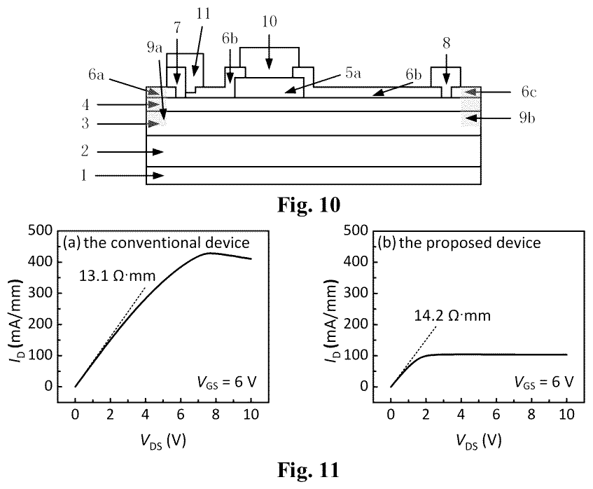

The E-mode GaN HEMT device structure with improved short-circuit capability prepared in this embodiment is shown in FIG. 10. The method of implementing the D-mode GaN HEMT in this embodiment is different from that in Embodiment 1. The D-mode GaN HEMT in this embodiment has a MIS gate structure.

Other structures and effects are similar to those of Embodiment 1.

What is claimed is:

1. A method for improving short-circuit capability of an enhancement-mode (E-mode) GaN HEMT, comprising
depositing metal in an active region between a gate and a source, adjacent to a source region of a conventional E-mode GaN HEMT, the metal being directly connected with the source of the conventional E-mode GaN HEMT to form a composite structure that combines a conventional E-mode GaN HEMT and a depletion-mode (D-mode) gate-source-shorted GaN HEMT, whereby forming a complete E-mode GaN HEMT with improved short-circuit capability.

2. The method of claim 1, wherein the E-mode GaN HEMT is a p-GaN gate HEMT, or a GaN HEMT with MIS-gate structure or a GaN HEMT with gate structure formed by fluorine ion implantation.

3. An E-mode GaN HEMT with improved short-circuit capability, comprising
a substrate;
a sequential stack of a buffer layer, a channel layer and a barrier layer on the substrate,
a source and a drain located on two sides of an active region on the barrier layer,
a gate structure located between the source and the drain, and a gate located on the gate structure,
a passivation layer formed between the source and the gate and also between the gate and the drain,
wherein metal is deposited in the active region between the gate and source and next to the source, directly connected with the source, and separated from the gate by the passivation layer.

4. The E-mode GaN HEMT of claim 3, wherein the metal directly connected with the source between the gate and the source is located on the barrier layer to form a Schottky gate D-mode gate-source-shorted GaN HEMT; or, the metal directly connected with the source between the gate and the source is located on the passivation layer to form a MIS gate D-mode gate-source-shorted GaN HEMT.

5. The E-mode GaN HEMT of claim 3, wherein the gate structure is a p-GaN gate structure, a MIS gate structure, or a gate structure formed by fluorine ion implantation.

6. The E-mode GaN HEMT of claim 3, wherein the substrate is a Si substrate, a SiC substrate, a Sapphire substrate, or a GaN substrate.

7. The E-mode GaN HEMT of claim 3, wherein the buffer layer comprises a materiel selected from GaN, AlN, InGaN, AlGaN, AlInGaN, or any combination thereof, and the channel layer is GaN, InGaN, AlGaN or AlInGaN.

8. The E-mode GaN HEMT of claim 3, wherein the barrier layer comprises a materiel selected from GaN, AlN, AlGaN, InGaN, AlInGaN, or any combination thereof.

9. A method for preparing an E-mode GaN HEMT of claim 3, a gate structure of the E-mode GaN HEMT being a p-type GaN cap layer, the method comprising the following steps:
1) sequentially growing a buffer layer, a channel layer, a barrier layer, and a p-type GaN layer on a substrate;
2) etching the p-type GaN layer to form a gate p-type GaN cap layer;
3) depositing a passivation layer on the barrier layer and the gate p-type GaN cap layer structure;
4) etching the passivation layer on the barrier layer to form grooves at the source and drain regions, and then depositing electrode metal to form the source and drain while retaining a groove for subsequent metal deposition between the gate and the source and next to the source;
5) forming a device isolation;
6) etching the passivation layer on the gate p-type GaN cap layer structure to form a groove for depositing a gate metal, and then depositing the gate metal to form the gate;
7) depositing metal in the groove between the gate and the source and next to the source, the metal being directly connected with the source to form a D-mode GaN HEMT metal.

10. The method of claim 9, wherein in step 4), the groove retained between the gate and the source and next to the source is located on the barrier layer, or on a partially etched passivation layer.
